(19) United States
(12) Patent Application Publication
(10) Pub. No.: US 2026/0033200 A1
(43) Pub. Date: Jan. 29, 2026

(54) DISPLAY PANEL, METHOD FOR MANUFACTURING SAME AND METHOD FOR DRIVING SAME, AND DISPLAY DEVICE

(71) Applicant: BOE Technology Group Co., Ltd., Beijing (CN)

(72) Inventor: Hao LIU, Beijing (CN)

(73) Assignee: BOE Technology Group Co., Ltd., Beijing (CN)

(21) Appl. No.: 18/995,169

(22) PCT Filed: Apr. 23, 2024
(86) PCT No.: PCT/CN2024/089255

§ 371 Date: Jan. 16, 2025

(30) Foreign Application Priority Data
May 17, 2023 (CN) 202310558383.3

(51) Int. Cl. H10K 59/35; G06V 40/13; G09G 3/3233; H10K 59/80

(52) U.S. Cl. CPC H10K 59/352; G09G 3/3233; H10K 59/353; H10K 59/80515; H10K 59/8792; G06V 40/1318; G09G 2300/0413; G09G 2300/0452; G09G 2300/0819; G09G 2300/0842; G09G 2300/0861; G09G 2310/08; G09G 2354/00

(57) ABSTRACT

Provided is a display panel. The display panel includes: a substrate; a plurality of pixels disposed on a side of the substrate, wherein each of the plurality of pixels includes a plurality of display sub-pixels for emitting different colors of visible light and at least one functional sub-pixel for emitting invisible light, the plurality of display sub-pixels being spaced apart from the at least one functional sub-pixel in any direction parallel to a bearing surface of the substrate; and a light-absorbing layer disposed between a functional sub-pixel and a display sub-pixel adjacent to each other, wherein the light-absorbing layer is configured to absorb invisible light emitted from the functional sub-pixel.

### CROSS-REFERENCE TO RELATED APPLICATIONS

The present disclosure is a U.S. national stage of international application No. PCT/CN2024/089255, filed on Apr. 23, 2024, which claims priority to Chinese Patent Application No. 202310558383.3, filed May 17, 2023 and entitled “DISPLAY PANEL, METHOD FOR MANUFACTURIN SAME, METHOD FOR DRIVING SAME, AND DISPLAY DEVICE”, the entire contents of each are incorporated herein by reference.

### TECHNICAL FIELD

The present disclosure relates to the field of display technology and more particularly to a display panel, a method for manufacturing the same and a method for driving the same, and a display device.

### BACKGROUND

With the development of display technology, various types of display devices including a display panel have emerged, for example, a portable handheld display device similar to a bracelet or a mobile terminal similar to a cellphone.

### SUMMARY

The present disclosure provides a display panel, a method for manufacturing the same and a method for driving the same, and a display device. The technical solutions are as follows.

In some embodiments of the present disclosure, a display panel is provided. The display panel includes:
a substrate:
a plurality of pixels disposed on a side of the substrate, wherein each of the plurality of pixels includes a plurality of display sub-pixels for emitting different colors of visible light and at least one functional sub-pixel for emitting invisible light, the plurality of display sub-pixels being spaced apart from the at least one functional sub-pixel in any direction parallel to a bearing surface of the substrate; and
a light-absorbing layer disposed between a functional sub-pixel and a display sub-pixel adjacent to each other, wherein the light-absorbing layer is configured to absorb invisible light emitted from the functional sub-pixel.

In some embodiments, a size of each of the at least one functional sub-pixel is smaller than a size of any one of the plurality of display sub-pixels.

In some embodiments, each of the plurality of pixels includes a red display sub-pixel for emitting red visible light, a green display sub-pixel for emitting green visible light, a blue display sub-pixel for emitting blue visible light, and a functional sub-pixel; wherein
the red display sub-pixel, the functional sub-pixel, and the green display sub-pixel are disposed in sequence in a first direction parallel to the bearing surface of the substrate, and each of the red display sub-pixel, the functional sub-pixel, and the green display sub-pixel is disposed in sequence with the blue display sub-pixel in a second direction parallel to the bearing surface of the substrate, the first direction intersecting the second direction: and an opening width of the functional sub-pixel, an opening width of the green display sub-pixel, an opening width of the red display sub-pixel, and an opening width of the blue display sub-pixel increase in sequence in the first direction; and an opening width of the functional sub-pixel, an opening width of the green display sub-pixel, an opening width of the red display sub-pixel, and an opening width of the blue display sub-pixel are all equal in the second direction.

In some embodiments, a spacing between the functional sub-pixel and the blue display sub-pixel is greater than a spacing between the functional sub-pixel and the red display sub-pixel and is greater than a spacing between the functional sub-pixel and the green display sub-pixel.

In some embodiments, the opening width of the functional sub-pixel in the first direction is less than the opening width of the functional sub-pixel in the second direction.

In some embodiments, the invisible light includes ultraviolet light or infrared light.

In some embodiments, each of the plurality of display sub-pixels and each of the at least one functional sub-pixel include an anode, a light-emitting layer, and a cathode layer that are laminated in a direction away from the substrate; at least the anodes and the light-emitting layers in the plurality of display sub-pixels and the at least one functional sub-pixel being respectively spaced apart from each other:
wherein the light-absorbing layer is disposed between the anode of the at least one functional sub-pixel and the anodes of the plurality of display sub-pixels.

In some embodiments, the display panel further includes: a pixel defining layer disposed between an anode of a functional sub-pixel and an anode of a display sub-pixel that are adjacent to each other; wherein
the pixel-defining layer is added with a light-absorbing material for absorbing invisible light emitted from the functional sub-pixel, the light-absorbing layer being the same as the pixel-defining layer; or
the light-absorbing layer is disposed between the anodes and the pixel defining layer, and the light-absorbing layer is added with a light-absorbing material for absorbing invisible light emitted from the functional sub-pixel.

In some embodiments, the light-absorbing material includes at least one of compounds including, but not limited to, a compound based on benzotriazoles and a compound based on o-hydroxyphenyltriazines.

In some embodiments, in the functional sub-pixel and the display sub-pixel adjacent to each other, a spacing between a side of the anode of the functional sub-pixel away from the substrate and the substrate is greater than or equal to a spacing between a side of the anode of the display sub-pixel away from the substrate and the substrate.

In some embodiments, in the functional sub-pixel and the display sub-pixel adjacent to each other, the anode of the functional sub-pixel is inclined in a direction away from the anode of the display sub-pixel.

In some embodiments, the display panel further includes: a planarization layer disposed between the substrate and the anodes; wherein
a thickness of a portion of the planarization layer that overlaps the anode of the functional sub-pixel is greater than or equal to a thickness of a portion of the planarization layer that overlaps the anode of the display sub-pixel, such that in the functional sub-pixel and the display sub-pixel adjacent to each other, the spacing between the side of the anode of the functional sub-pixel away from the substrate and the substrate is greater than or equal to the spacing between the side of the anode of the display sub-pixel away from the substrate and the substrate, and/or
the portion of the planarization layer that overlaps the anode of the functional sub-pixel is inclined away from the portion of the planarization layer that overlaps the anode of the display sub-pixel, such that in the functional sub-pixel and the display sub-pixel adjacent to each other, the anode of the functional sub-pixel is inclined in a direction away from the anode of the display sub-pixel.

In some embodiments, the anode of the functional sub-pixel includes a first portion close to a blue display sub-pixel in the plurality of display sub-pixels and a second portion away from the blue display sub-pixel in the plurality of display sub-pixels, wherein a spacing between a surface of the first portion away from the substrate and the substrate is greater than a spacing between a surface of the second portion away from the substrate and the substrate.

In some embodiments, each of the plurality of display sub-pixels and each of the at least one functional sub-pixel include a pixel circuit and a light-emitting element; the pixel circuit in each of the plurality of display sub-pixels and the pixel circuit in each of the at least one functional sub-pixel both including:
a reset sub-circuit, coupled to a reset terminal, an initial power supply terminal, a first node, and the light-emitting element, and configured to control, based on a reset signal provided by the reset terminal, switching on and off of a connection between the initial power supply terminal and the first node and switching on and off of a connection between the initial power supply terminal and the light-emitting element;
a light emission control sub-circuit, coupled to a light emission control terminal, a driving power supply terminal, a second node, a third node, and the light-emitting element, and configured to control, based on a light emission control signal provided by the light emission control terminal, switching on and off of a connection between the driving power supply terminal and the second node and switching on and off of a connection between the third node and the light-emitting element;
a drive sub-circuit, coupled to the first node, the second node, and the third node, and configured to transmit a light emission driving signal to the third node based on a potential of the first node and a potential of the second node; and
a potential adjustment sub-circuit, coupled to the first node and the driving power supply terminal, and configured to adjust the potential of the first node based on a driving power supply signal provided by the driving power supply terminal;
the pixel circuit in each of the plurality of display sub-pixels further includes: a data writing sub-circuit, coupled to a gate signal terminal, a data signal terminal, the first node, the second node, and the third node, and configured to control, based on a gate driving signal provided by the gate signal terminal, switching on and off of a connection between the data signal terminal and the second node and switching on and off of a connection between the third node and the first node;
wherein in the pixel circuit of each of the plurality of display sub-pixels and the pixel circuit of each of the at least one functional sub-pixel, at least one of the reset sub-circuit, the drive sub-circuit, and the potential adjustment sub-circuit is shared.

In some embodiments, the pixel circuit of each of the at least one functional sub-pixel further includes a data writing sub-circuit shared with the data writing sub-circuit included in the pixel circuit in each of the plurality of display sub-pixels.

In some embodiments, the reset sub-circuit includes a first transistor and a second transistor; the light emission control sub-circuit includes a third transistor and a fourth transistor; the drive sub-circuit includes a fifth transistor; the data writing sub-circuit includes a sixth transistor and a seventh transistor; and the potential adjustment sub-circuit includes a storage capacitor; wherein
a gate of the first transistor and a gate of the second transistor are coupled to the reset terminal, a first electrode of the first transistor and a second electrode of the second transistor are coupled to the initial power supply terminal, a second electrode of the first transistor is coupled to the first node, and a first electrode of the second transistor is coupled to the light-emitting element:
a gate of the third transistor and a gate of the fourth transistor are coupled to the light emission control terminal, a first electrode of the third transistor is coupled to the driving power supply terminal, a second electrode of the third transistor is coupled to the second node, a first electrode of the fourth transistor is coupled to the third node, and a second electrode of the fourth transistor is coupled to the light-emitting element;
a gate of the fifth transistor is coupled to the first node, a first electrode of the fifth transistor is coupled to the second node, and a second electrode of the fifth transistor is coupled to the third node;
a gate of the sixth transistor and a gate of the seventh transistor are coupled to the gate signal terminal, a first electrode of the sixth transistor is coupled to the data signal terminal, a second electrode of the sixth transistor is coupled to the second node, a first electrode of the seventh transistor is coupled to the third node, and a second electrode of the seventh transistor is coupled to the first node: and
one terminal of the storage capacitor is coupled to the driving power supply terminal, and another terminal of the storage capacitor is coupled to the first node.

In some embodiments, the substrate has a display region and a peripheral region at least partially surrounding the display region;
wherein the plurality of display sub-pixels are disposed in the display region, and the at least one functional sub-pixel is disposed in at least one of the display region or the peripheral region.

In some embodiments, the display panel further includes: a dummy pixel circuit disposed in the peripheral region;
wherein a pixel circuit included in each of the at least one functional sub-pixel is shared with the dummy pixel circuit.

In some embodiments, the at least one functional sub-pixel is disposed in the display region: and the display region includes a fingerprint region provided with a fingerprint sensor and a main display region at least partially surrounding the fingerprint region;
wherein the plurality of display sub-pixels are disposed in the fingerprint region and the main display region, and the at least one functional sub-pixel is disposed in the fingerprint region.

In some embodiments of the present disclosure, a method for manufacturing a display panel is provided. The method is applicable for manufacturing the display panel as described above. The method includes:
providing a substrate;
forming a plurality of pixels on a side of the substrate, wherein each of the plurality of pixels formed includes a plurality of display sub-pixels for emitting different colors of visible light and at least one functional sub-pixel for emitting invisible light, the plurality of display sub-pixels being spaced apart from the at least one functional sub-pixel in any direction parallel to a bearing surface of the substrate; and
forming a light-absorbing layer between a functional sub-pixel and a display sub-pixel adjacent to each other, wherein the light-absorbing layer is configured to absorb invisible light emitted from the functional sub-pixel.

In some embodiments, each of the plurality of display sub-pixels and each of the at least one functional sub-pixel include an anode, a light-emitting layer, and a cathode layer that are laminated in a direction away from the substrate; at least the anodes and the light-emitting layers in the plurality of display sub-pixels and the at least one functional sub-pixel being respectively spaced apart from each other; and
the method further includes:
forming a planarization layer between the substrate and the anodes using a halftone mask; wherein
a thickness of a portion of the formed planarization layer that overlaps the anode of the functional sub-pixel is greater than or equal to a thickness of a portion of the planarization layer that overlaps the anode of the display sub-pixel, such that in the functional sub-pixel and the display sub-pixel adjacent to each other, a spacing between a side of the anode of the functional sub-pixel away from the substrate and the substrate is greater than or equal to a spacing between a side of the anode of the display sub-pixel away from the substrate and the substrate;
and/or
the portion of the formed planarization layer that overlaps the anode of the functional sub-pixel is inclined away from the portion of the planarization layer that overlaps the anode of the display sub-pixel, such that in the functional sub-pixel and the display sub-pixel adjacent to each other, the anode of the functional sub-pixel is inclined in a direction away from the anode of the display sub-pixel.

In some embodiments of the present disclosure, a method for driving a display panel. The method is applicable for driving the display panel as described above. The method includes:
driving, in response to a received display instruction, a plurality of display sub-pixels in a pixel included in the display panel to emit different colors of visible light, such that the display panel displays an image: and
driving, in response to a received function instruction, at least one functional sub-pixel in the pixel to emit invisible light, such that the display panel performs a function matching the invisible light.

In some embodiments of the present disclosure, a display device. The display device includes: a drive circuit, and the display panel as described above.

The drive circuit is coupled to the display panel, and the drive circuit is configured to drive a plurality of display sub-pixels in a pixel included in the display panel to emit different colors of visible light and configured to drive at least one functional sub-pixel in the pixel to emit invisible light.

### BRIEF DESCRIPTION OF DRAWINGS

For a clearer description of the technical solutions in the embodiments of the present disclosure, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a schematic structural diagram of pixel arrangement in a display panel according to some embodiments of the present disclosure;

FIG. 2 is a sectional view of a display panel according to some embodiments of the present disclosure;

FIG. 3 is a schematic structural diagram of pixel arrangement in another display panel according to some embodiments of the present disclosure;

FIG. 4 is a schematic structural diagram of pixel arrangement in another display panel according to some embodiments of the present disclosure;

FIG. 5 is a schematic structural diagram of pixel arrangement in another display panel according to some embodiments of the present disclosure;

FIG. 6 is a sectional view of another display panel according to some embodiments of the present disclosure;

FIG. 7 is a sectional view of another display panel according to some embodiments of the present disclosure;

FIG. 8 is a schematic structural diagram of a pixel according to some embodiments of the present disclosure;

FIG. 9 is a schematic structural diagram of a pixel circuit according to some embodiments of the present disclosure;

FIG. 10 is an operating timing diagram of a pixel circuit according to some embodiments of the present disclosure;

FIG. 11 is an operating timing diagram of another pixel circuit according to some embodiments of the present disclosure;

FIG. 12 is a schematic diagram of a layout of a display panel according to some embodiments of the present disclosure;

FIG. 13 is a flowchart of a method for manufacturing a display panel according to some embodiments of the present disclosure;

FIG. 14 is a flowchart of a method for driving a display panel according to some embodiments of the present disclosure; and

FIG. 15 is a schematic structural diagram of a display device according to some embodiments of the present disclosure.

### DETAILED DESCRIPTION

In order to make the objects, technical solutions and advantages of the present disclosure clearer, the embodiments of the present disclosure will be described in further detail below in conjunction with the accompanying drawings.

In the related art, a display panel generally includes a substrate and a plurality of pixels disposed on the substrate. Each pixel includes a plurality of sub-pixels for emitting light of different colors, for example, a red display sub-pixel for emitting red light, a green display sub-pixel for emitting green light, and a blue display sub-pixel for emitting blue light. Different images can be displayed when the plurality of pixels emit red light, green light and blue light.

However, since the existing display panel can only be used for displaying images, its function is relatively single.

The transistors used in all the embodiments of the present disclosure are field-effect transistors or other devices having the same characteristics. The transistors used in the embodiments of the present disclosure are mainly switching transistors according to their functions in the circuit. Since a source and a drain of the switching transistor used herein are symmetrical, the source and the drain are interchangeable. In the embodiments of the present disclosure, the source is referred to as a first electrode and the drain is referred to as a second electrode, or the drain is referred to as a first electrode and the source is referred to as a second electrode. According to the form in the drawings, it is specified that an intermediate terminal of the transistor is a gate, a signal input terminal is the source, and a signal output terminal is the drain. In addition, the switching transistors used in the embodiments of the present disclosure include P-type transistors or N-type transistors. The P-type transistor is turned on when the gate is at a low level and is turned off when the gate is at a high level, and the N-type transistor is turned on when the gate is at a high level and turned off when the gate is at a low level. In addition, the signals in the embodiments of the present disclosure each correspond to an effective potential and an ineffective potential. The effective potential and the ineffective potential only represent that the signal has potentials with two different state quantities, but do not represent that the effective potential or the ineffective potential has a specific value.

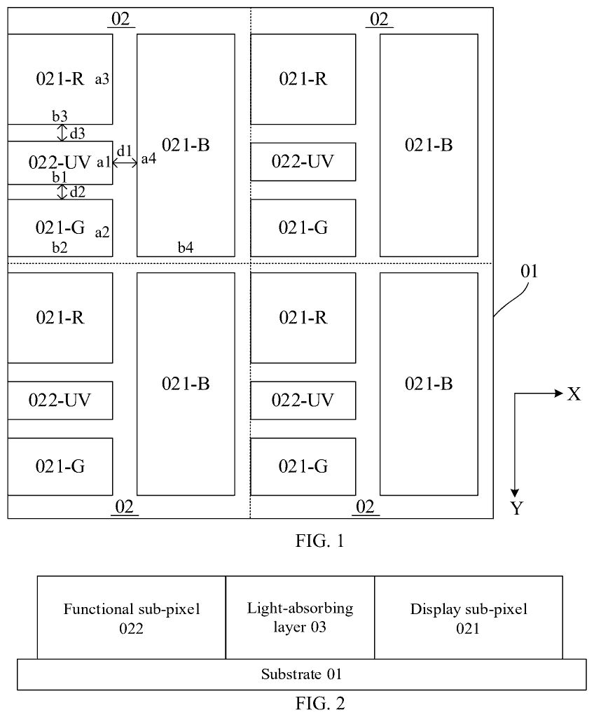

FIG. 1 is a schematic structural diagram of a display panel according to some embodiments of the present disclosure. As shown in FIG. 1. the display panel includes a substrate 01 and a plurality of pixels 02 disposed on a side of the substrate 01.

Each pixel 02 includes a plurality of display sub-pixels 021 for emitting different colors of visible light (e.g., blue light) and at least one functional sub-pixel 022 for emitting invisible light (e.g., ultraviolet light).

For example, each pixel 02 shown in FIG. 1 includes three display sub-pixels 021 and one functional sub-pixel 022. On this basis, it may be considered that one functional sub-pixel 022 is arranged to correspond to a plurality of display sub-pixels 021. In some other embodiments, each pixel 02 includes a plurality of functional sub-pixels 022. On this basis, it may be considered that one functional sub-pixel 022 is arranged to correspond to one display sub-pixel 021.

On the basis that the display sub-pixels 021 emit different colors of visible light, an image is displayed, that is, the display panel displays an image through the display sub-pixels 021 included in the pixels 02, thereby performing the display functions. On the basis that the display sub-pixels 021 emit invisible light, functions matching the type of the invisible light can be performed, that is, the display panel performs the non-display functions through the functional sub-pixels 022. For example, in the case that the invisible light is ultraviolet light, the non-display function is a sterilizing function that matches the ultraviolet light. It can be seen that, in the display panel provided in the embodiments of the present disclosure, the sub-pixels emitting invisible light and the sub-pixels emitting visible light are provided integrally and the display panel can achieve the non-display functions while achieving the display functions. Thus, the display panel provided in the embodiments of the present disclosure has richer functions.

With continued reference to FIG. 1, in the embodiments of the present disclosure, in each pixel 02, the plurality of display sub-pixels 021 are spaced apart from (i.e., not in contact) the at least one functional sub-pixel 022 in any direction parallel to the bearing surface of the substrate 01. In this way, the display sub-pixels 021 can be prevented from being damaged due to the radiation of the invisible light emitted from the functional sub-pixels 022, thereby preventing the light-emitting efficiency and lifetime of the display sub-pixels 021 from being affected.

As can be further seen from the sectional view of the display panel shown in FIG. 2. the display panel provided in the embodiments of the present disclosure further includes a light-absorbing layer 03 (which may also be considered as an isolation pillar spacing the functional sub-pixel 022 from the display sub-pixel 021) disposed between the functional sub-pixel 022 and the display sub-pixel 021 that are adjacent to each other. The light-absorbing layer 03 is configured to absorb the invisible light emitted from the functional sub-pixel 022. For example, the light-absorbing layer 03 is a black matrix layer, or a light-absorbing material is added to the light-absorbing layer 03. In this way, the display sub-pixels 021 can be further prevented from being damaged due to the radiation of the invisible light emitted from the functional sub-pixels 022, thereby affectively preventing the light-emitting efficiency and lifetime of the display sub-pixels 021 from being affected.

In summary, the embodiments of the present disclosure provide a display panel. The display panel includes a substrate and a plurality of pixels disposed on a side of the substrate. Each pixel includes a plurality of display sub-pixels for emitting different colors of visible light and at least one functional sub-pixel for emitting invisible light. On the basis that the plurality of display sub-pixels are lit to emit different colors of visible light, the display panel displays an image. On the basis that the functional sub-pixels emit invisible light (e.g., ultraviolet light), the display panel performs a function (e.g., sterilizing function) that matches the invisible light. Thus, the display panel provided in the embodiments of the present disclosure has richer functions.

In addition, in the embodiments of the present disclosure, the functional sub-pixels are spaced apart from the display sub-pixels in any direction, and a light-absorbing layer configured to absorb the invisible light is further provided between the functional sub-pixel and the display sub-pixel that are adjacent to each other. Therefore, on the premise that the functions are enriched, the display sub-pixels can be prevented from being damaged due to the radiation of the invisible light emitted from the functional sub-pixels, and the display sub-pixels are be protected.

In some embodiments of the present disclosure, the invisible light emitted from the functional sub-pixel 022 includes ultraviolet light or infrared light. The ultraviolet light is also referred to as ultraviolet (UV) rays, and accordingly, the functional sub-pixel 022 emitting the ultraviolet light is also referred to as a UV pixel. Similarly, the infrared light is also referred to as infrared rays.

For example, in the case that the invisible light is ultraviolet light, when the functional sub-pixel 022 lights up to emit the ultraviolet light, the display panel achieves the non-display functions such as self-cleaning of the display panel, sterilization and disinfection, and/or radiation onto other objects for cleaning. Accordingly, the display panel including the functional sub-pixel 022 is appliable for display devices on which viruses are easily attached because they are touched whenever and anywhere or are exposed to various external environments, for example, portable handheld devices such as bracelets. The display panel including the functional sub-pixel 022 is applicable for such display devices for the purposes of self-cleaning and sterilization. In the case that the invisible light is infrared light, when the functional sub-pixel 022 lights up to emit the infrared light, the display panel achieves the non-display functions such as infrared radiation therapy or imaging. Accordingly, the display panel including the functional sub-pixel 022 is appliable to some treatment scenarios. It should be noted that some functions of the ultraviolet light and the infrared light are only illustratively described herein, without being limiting thereto. The invisible light is not limited to the infrared light or the ultraviolet light as described in the above embodiments.

In some embodiments, the functional sub-pixels 022 emit the same or different invisible light. For example, the functional sub-pixels 022 all emit ultraviolet light or infrared light; or some of the plurality of functional sub-pixels 022 are configured to emit infrared light, and the other functional sub-pixels 022 are configured to emit ultraviolet light. On the basis that the functional sub-pixels 022 emit different invisible light, the functions of the display panel can be further enriched.

In some embodiments, as can be further seen from FIG. 1, the size of each functional sub-pixel 022 is less than the size of any one of the display sub-pixels 021. The size refers to the area of the orthographic projection of the sub-pixel on the substrate 01. Thus, the functional sub-pixels 022 emit less invisible light, which can further prevent the display sub-pixels 021 from being damaged due to the irradiation of the invisible light emitted from the functional sub-pixels 022.

In some embodiments, as can be further seen from FIG. 1, each pixel 02 in the embodiments of the present disclosure includes a red display sub-pixel 021 for emitting red (R) visible light, a green display sub-pixel 021 for emitting green (G) visible light, a blue display sub-pixel 021 for emitting blue (B) visible light, and a functional sub-pixel 022.

For example, the invisible light emitted from the functional sub-pixel 022 is the UV light as described in the above embodiments. On this basis, in the figure, the red display sub-pixel 021 is marked as 021-R, the green display sub-pixel 021 is marked as 021-G, the blue display sub-pixel 021 is marked as 021-B, and the functional sub-pixel 022 is marked as 022-UV.

In some embodiments, as can be further seen from FIG. 1, the red display sub-pixel 021-R, the functional sub-pixel 022-UV, and the green display sub-pixel 021-G are sequentially arranged in the first direction Y parallel to the bearing surface of the substrate 01, and each of the red display sub-pixel 021-R, the functional sub-pixel 022-UV, and the green display sub-pixel 021-G and the blue display sub-pixel 021-B are sequentially arranged in the second direction X parallel to the bearing surface of the substrate 01.

The first direction Y intersects the second direction X. For example, the first direction Y is perpendicular to the second direction X in FIG. 1. On the basis that the plurality of pixels 02 are arranged in an array, one of the first direction Y and the second direction X is considered as a pixel row direction, and the other direction is considered as a pixel column direction.

In addition, in the first direction Y, the opening width al of the functional sub-pixel 022-UV. the opening width a2 of the green display sub-pixel 021-G. the opening width a3 of the red display sub-pixel 021-R, and the opening width a4 of the blue display sub-pixel 021-B increase in sequence. In the second direction X, the opening width b1 of the functional sub-pixel 022-UV, the opening width b2 of the green display sub-pixel 021-G, the opening width b3 of the red display sub-pixel 021-R, and the opening width b4 of the blue display sub-pixel 021-B are equal.

That is, as can be seen from FIG. 1, in the embodiments of the present disclosure, the opening widths of the sub-pixels (including the display sub-pixels 021 and the functional sub-pixel (22) in the pixel 02 are set to be equal to each other in the X-direction, and the opening width of the functional sub-pixel 022-UV is reduced as much as possible in the Y-direction, such that the opening width of the functional sub-pixel 022-UV is the smallest. In this way, the size of the functional sub-pixel 022-UV is minimized, thereby ensuring that less invisible light (e.g., UV light) irradiates the blue display sub-pixel 021-B, which is more vulnerable to radiation of the invisible light, among the red display sub-pixel 021-R, the green display sub-pixel 021-G, and the blue display sub-pixel 021-B, to reliably prevent the blue display sub-pixel 021-B from being damaged. The opening width of the functional sub-pixel 022-UV may also be minimized in the second direction X, thereby ensuring that less invisible light irradiates the red display sub-pixel 021-R and the green display sub-pixel 021-G, to protect the red display sub-pixel 021-R and the green display sub-pixel 021-G.

In some embodiments, as can be further seen from FIG. 1, the spacing d1 between the functional sub-pixel 022-UV and the blue display sub-pixel 021-B is greater than the spacing d2 between the functional sub-pixel 022-UV and the green display sub-pixel 021-G and greater than the spacing d3 between the functional sub-pixel 022-UV and the red display sub-pixel 021-R. The spacing d3 between the functional sub-pixel 022-UV and the red display sub-pixel 021-R is equal to the spacing d2 between the functional sub-pixel 022-UV and the green display sub-pixel 021-G. That is, the spacing between the functional sub-pixel 022-UV and the blue display sub-pixel 021-B is set to be the largest, which can further ensure that less invisible light irradiates the blue display sub-pixel 021-B which is more vulnerable to the radiation of the invisible light, i.e., reliably protecting the blue display sub-pixel 021-B.

In some embodiments, as can be further seen from FIG. 1, the opening width al of the functional sub-pixel 022 in the first direction Y is less than the opening width b1 of the functional sub-pixel 022 in the second direction X, which can further ensure that less invisible light irradiates the blue display sub-pixel 021-B which is more vulnerable to the radiation of the invisible light, i.e., reliably protecting the blue display sub-pixel 021-B.

It is to be noted that the arrangement of pixels shown in FIG. 1 is arrangement of a real RGB, and the functional sub-pixel 022 and the display sub-pixel RGB are arranged in one-to-one correspondence. For the display panel provided in the embodiments of the present disclosure, it is not limited to the real RGB and the one-to-one arrangement shown in FIG. 1.

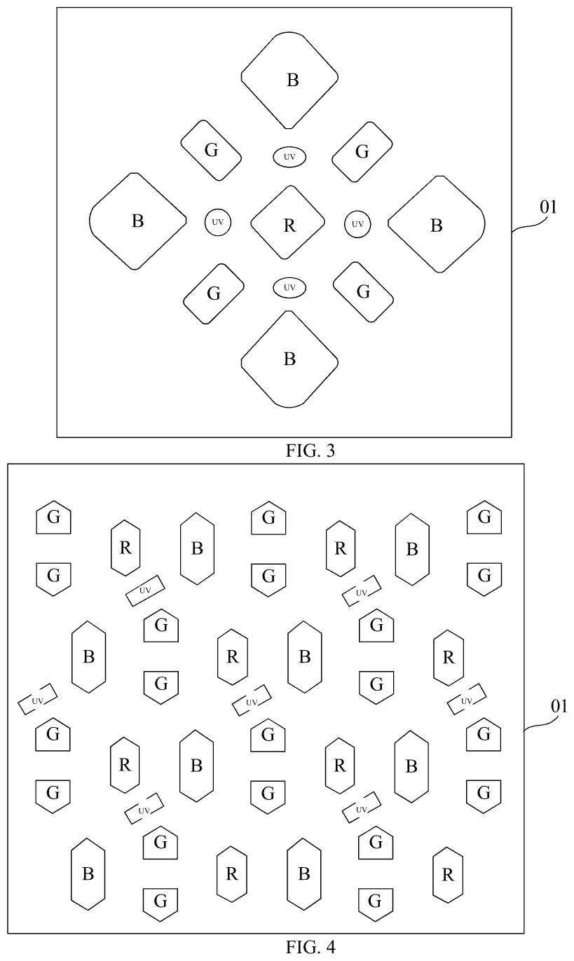

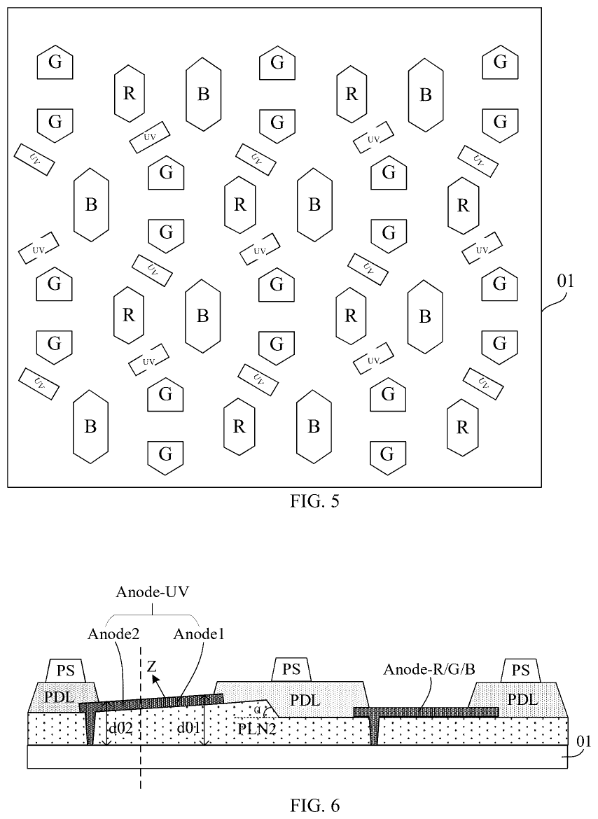

For example, still taking an example where the invisible light emitted from the functional sub-pixel 022 is ultraviolet UV, i.e., the functional sub-pixel 022 is marked as UV, referring to the schematic diagram of another display panel shown in FIG. 3, each pixel may also be arranged in a blue diamond manner, i.e., in a blue diamond pixel array. Alternatively, referring to the schematic diagrams of another display panel shown in FIG. 4 and FIG. 5, each pixel may also be arranged in a GGRB manner, i.e., in a GRRB pixel array. On the basis of this embodiment, it may be considered that each pixel 02 includes two green display sub-pixels 021-G, one red display sub-pixel 021-R. and one blue display sub-pixel 021-B. In addition, in the arrangements shown in FIG. 3 and FIG. 4, each pixel 02 includes one functional sub-pixel 022-UV, that is, the functional sub-pixel 022-UV and the RGB/GGRB are arranged in one-to-one correspondence. In the arrangement shown in FIG. 5, each pixel 02 includes a plurality of functional sub-pixels 022-UV, that is. the functional sub-pixels 022-UV and the RGB/GGRB are arranged in one-to-many correspondence. It is favorable for the embedded integration design on a display panel with high PPI. PPI refers to the number of pixels per inch in the display panel, with an English full name of per pixel inch. The above arrangements are merely illustrative but not limiting. Only R, G, B and UV are marked in FIG. 3 to FIG. 5.

In some embodiments, taking an example where the display sub-pixels 021 include the red display sub-pixel 021-R, the green display sub-pixel 021-G, and the blue display sub-pixel 021-B, and the functional sub-pixel 022 is configured to emit the ultraviolet light. FIG. 6 shows a sectional view of another display panel. As shown in FIG. 6, the display sub-pixel 021 and the functional sub-pixel 022 in the embodiments of the present disclosure both include an anode Anode, a light-emitting layer EL, and a cathode layer C that are laminated in the direction away from the substrate 01. That is, the display sub-pixel 021 and the functional sub-pixel 022 both include an organic light-emitting diode (OLED), and on this basis, the display sub-pixel 021 being spaced apart from the functional sub-pixel 022 refers to that the anodes Anode and the light-emitting layers E are respectively spaced apart from each other.

It is to be noted that FIG. 6 illustratively shows the anode Anode only, and the anode Anode of the display sub-pixel 021 is marked as Anode-R/G/B, and the anode Anode of the functional sub-pixel 022 is marked as Anode-UV. On this basis, as can be further seen from FIG. 6, the light-absorbing layer 03 is disposed between the anode Anode (i.e., Anode-UV) of the functional sub-pixel 022 and the anode (i.e., Anode-R/G/B) of the display sub-pixel 021.

In some embodiments, as can be further seen from FIG. 6, the display panel in embodiments of the present disclosure further includes a pixel defining layer (PDL) disposed between the anode Anode of the functional sub-pixel 022 and the anode Anode of the display sub-pixel 021 that are adjacent.

A light-absorbing material for absorbing the invisible light emitted from the functional sub-pixel 022 is added to the pixel defining layer PDL. On this basis, the light-absorbing layer 03 is the same as the pixel defining layer PDL, that is, the light-absorbing material is directly added to the pixel defining layer PDL for defining adjacent sub-pixels, and the pixel defining layer PDL added with the light-absorbing material is reused as the light-absorbing layer 03. In this way, on the premise of saving costs, the following purposes can be achieved, i.e., not affecting the emission of the visible light and its optical path, and reliably absorbing a portion of the invisible light (e.g., UV) irradiating the pixel defining layer PDL, such that the invisible light can reliably radiate in the direction perpendicular to the anode Anode towards the outside of the display panel, thereby avoiding damage to the light-emitting layer EL of the adjacent display sub-pixel 021. Thus, the light-emitting lifetime of the display sub-pixel 021 is greatly increased. Moreover, it can prevent the invisible light from being reflected multiple times between adjacent pixel-defining layers PDL to be refracted to the display backplane included in the display panel, thereby preventing the invisible light from affecting the characteristics of the circuit devices (e.g., transistors) on the display backplane, and ensuring a better electrical reliability of the display backplane.

In some other embodiments, the light-absorbing layer 03 is disposed between the anodes Anode and the pixel-defining layer PDL, and the light-absorbing layer 03 is added with the light-absorbing material for absorbing the invisible light emitted from the functional sub-pixel 022. That is. a light-absorbing layer 03 is additionally provided between the pixel-defining layer PDL and the anode Anode to specifically absorb the invisible light, to achieve the same technical effect as reusing the pixel-defining layer PDL to absorb the invisible light. On the basis of this embodiment, the light-absorbing layer 03 is also referred to as an isolation pillar.

In some embodiments, the light-absorbing material includes at least one of the following compounds; a compound based on benzotriazoles, a compound based on o-hydroxyphenyltriazines. or the like. The light-absorbing material is mostly used for absorbing ultraviolet light UV. In some other embodiments, the light-absorbing layer 03 (here, the reused pixel-defining layer PDL or the additionally provided light-absorbing layer 03) is directly provided as a black film layer for absorbing the invisible light.

In some embodiments, as can be further seen from the sectional view shown in FIG. 6, in the embodiments of the present disclosure, in the functional sub-pixel 022 and the display sub-pixel 021 adjacent to each other, the anode Anode of the functional sub-pixel 022 is inclined in the direction Z away from the anode Anode of the display sub-pixel 021. That is, the flatness of the anode Anode is changed such that the functional sub-pixel 022 faces away from the display sub-pixel 021. Thus, the functional sub-pixel 022 emits the invisible light in the direction Z facing away from the display sub-pixel 021, which can further prevent the invisible light emitted from the functional sub-pixel 022 from radiating the display sub-pixel 021 to damage the display sub-pixel 021.

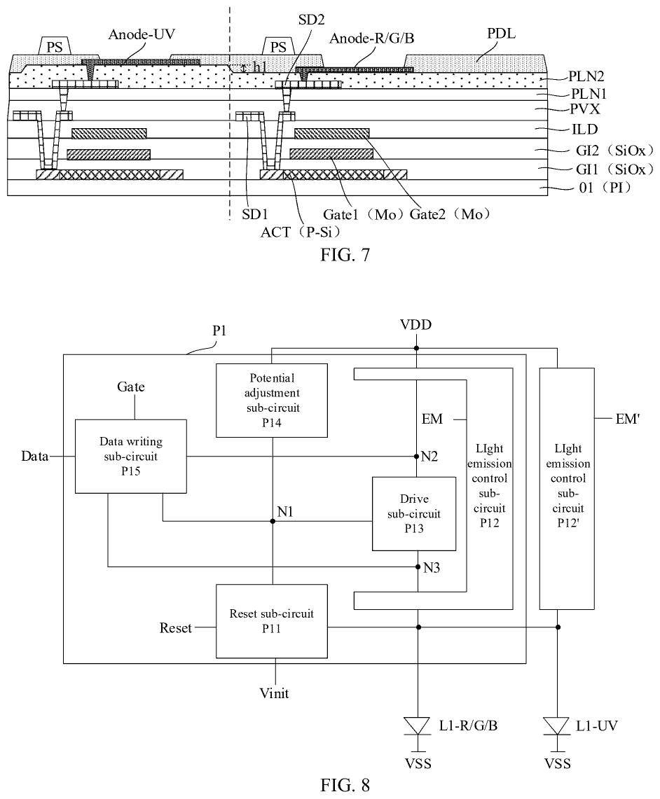

In some embodiments, still taking an example where the display sub-pixels 021 include a red display sub-pixel 021-R, a green display sub-pixel 021-G, and a blue display sub-pixel 021-B, and the functional sub-pixel 022 is configured to emit ultraviolet light UV, as can be seen from another sectional view shown in FIG. 7, in the embodiments of the present disclosure, in the functional sub-pixel 022 and the display sub-pixel 021 adjacent to each other, the spacing between the side of the anode Anode of the functional sub-pixel 022 away from the substrate 01 and the substrate 01 is greater than or equal to the spacing between the side of the anode Anode of the display sub-pixel 021 away from the substrate 01 and the substrate 01, that is, the anode Anode of the functional sub-pixel 022 is farther away from the substrate 01 than the anode of the display sub-pixel 021 is, or the anode Anode of the functional sub-pixel 022 and the anode of the display sub-pixel 021 are located at the same level. It should be noted that in FIG. 7, the anode Anode of the display sub-pixel 021 is also marked as Anode-R/G/B. and the anode Anode of the functional sub-pixel 022 is also marked as Anode-UV.

For example, in the sectional view shown in FIG. 7, the spacing between the side of the anode Anode of the functional sub-pixel 022 away from the substrate 01 and the substrate 01 is greater than the spacing between the side of the anode Anode of the display sub-pixel 021 away from the substrate 01 and the substrate 01. The anode Anode of the functional sub-pixel 022 is set to be farther away from the substrate 01 than the anode Anode of the display sub-pixel 021, that is, the height of the anode Anode of the functional sub-pixel 022 is set to be greater than the height of the anode Anode of the display sub-pixel 021, such that less invisible light radiates sideways downwardly to the display sub-pixel 021 emitting visible light, thereby further reducing the damage to the display sub-pixels 021 due to radiation and improves the service life of the display devices emitting visible light (i.e., the display sub-pixels 021).

In the case that the resolution of the display panel is high and the spacing between the sub-pixels (including the display sub-pixels 021 and the functional sub-pixel 022) is small, the spacing between the side of the anode Anode of the functional sub-pixel 022 away from the substrate 01 and the substrate 01 is set to be equal to the spacing between the side of the anode Anode of the display sub-pixel 021 away from the substrate 01 and the substrate 01, that is, the anode Anode of the display sub-pixel 021 is set to be at the same level as the anode Anode of the functional sub-pixel 022, so as to prevent the invisible light emitted from the functional sub-pixel 022 from affecting the optical path of the visible light emitted from the display sub-pixel 021.

In addition, as can be seen from FIG. 6 and FIG. 7, on the basis of setting the anode Anode of the functional sub-pixel 022 to be farther away from the substrate 01 than the anode of the display sub-pixel 021, the anode Anode of the functional sub-pixel 022 is further set to be inclined in the direction Z away from the anode Anode of the display sub-pixel 021, which can between protect the display sub-pixel 021. In some embodiments, the anode Anode of the functional sub-pixel 022 is set to be farther away from the substrate 01 than the anode of the display sub-pixel 021, and the anode Anode of the functional sub-pixel 022 and the anode Anode of the display sub-pixel 021 are both set to be flat, as shown in FIG. 7. Alternatively, the anode Anode of the functional sub-pixel 022 is set to be inclined in the direction Z away from the anode Anode of the display sub-pixel 021, and the anode Anode of the display sub-pixel 021 is set to be at the same level as the anode Anode of the functional sub-pixel 022. The combinations of the above solutions are not limited in the embodiments of the present disclosure.

In some embodiments, as can be seen from FIG. 6 and FIG. 7, the display panel in the embodiments of the present disclosure further includes a planarization (PLN) layer disposed between the substrate 01 and the anodes Anode.

The thickness of the portion of the planarization layer PLN that overlaps the anode Anode of the functional sub-pixel 022 is greater than or equal to the thickness of the portion of the planarization layer PLN that overlaps the anode Anode of the display sub-pixel 021. Therefore, in the functional sub-pixel 022 and the display sub-pixel 021 adjacent to each other, the spacing between the side of the anode Anode of the functional sub-pixel 022 away from the substrate 01 and the substrate 01 is greater than or equal to the spacing between the side of the anode Anode of the display sub-pixel 021 away from the substrate 01 and the substrate 01.

As can be seen from FIG. 6, the portion of the planarization layer PLN that overlaps the anode Anode of the functional sub-pixel 022 is inclined away from the portion of the planarization layer PLN that overlaps the anode Anode of the display sub-pixel 021. Therefore, in the functional sub-pixel 022 and the display sub-pixel 021 adjacent to each other, the anode Anode of the functional sub-pixel 022 is inclined in the direction Z away from the anode Anode of the display sub-pixel 021.

That is, on the one hand, the thickness of the portion of the planarization layer PLN disposed at the side of the anode Anode of the functional sub-pixel 022 is set to be different from the thickness of the portion of the planarization layer PLN disposed at the side of the anode Anode of the display sub-pixel 021, such that the height of the anode Anode of the functional sub-pixel 022 is different from the height of the anode Anode of the display sub-pixel 021. Similarly, on the other hand, the portion of the planarization layer PLN disposed at the side of the anode Anode of the functional sub-pixel 022 is set to be inclined in the direction in which the upper surface of the side, away from the substrate 01, of the portion faces away from the display sub-pixel 021, such that the anode Anode of the functional sub-pixel 022 is inclined in the direction Z away from the anode Anode of the display sub-pixel 021.

For example, in conjunction with FIG. 6, when the portion disposed at the side of the anode Anode of the functional sub-pixel 022 is inclined in the direction in which the upper surface of the side, away from the substrate 01, of the portion faces away from the display sub-pixel 021, the inclination angle a ranges is about 2 degrees to 10 degrees, for example, 5 degrees. In conjunction with FIG. 7, the thickness difference h1 between the thickness of the portion disposed at the side of the anode Anode of the functional sub-pixel 022 and the thickness of the portion disposed at the side of the anode Anode of the display sub-pixel 021 is in a unit of a micrometer scale, for example, about 2 micrometers to 10 micrometers.

In some embodiments, when the display panel is manufactured, a halftone mask is used to form the planarization layer PLN with different thicknesses at different locations or the planarization layer PLN having an inclined portion in the above-described embodiments by a single patterning process. The single patterning process includes multiple exposures, developing or etching processes.

In some other embodiments, other film layers are additionally provided between the anode Anode and the planarization layer PLN, such that the height of the anode Anode of the functional sub-pixel 022 is different from the height of the anode of the display sub-pixel 021, or the anode Anode of the functional sub-pixel 022 is inclined in the direction Z away from the anode Anode of the display sub-pixel 021. The specific implementations are not limited in the embodiments of the present disclosure.

In some embodiments, as can be further seen from FIG. 7, the display panel in the embodiments of the present disclosure further includes another planarization layer PLN disposed between the planarization layer PLN in the above-described embodiments and the substrate 01. For differentiation purposes, the planarization layer close to the substrate 01 is marked as PLN1, and the planarization layer farther away from the substrate 01 is marked as PLN2 in the figure. Accordingly, the thickness of the portion of the planarization layer PLN2 disposed at the side of the anode Anode of the functional sub-pixel 022 is different from the thickness of the portion of the planarization layer PLN2 disposed at the side of the anode Anode of the display sub-pixel 021. Alternatively, the portion of the planarization layer PLN2 disposed at the side of the anode Anode of the functional sub-pixel 022 is set to be inclined in the direction in which the upper surface of the side, away from the substrate 01, of the portion faces away from the display sub-pixel 021.

Additionally, the display panel in the embodiments of the present disclosure further includes an active layer ACT, a first gate insulating layer GI1, a first gate metal layer Gate, a second gate insulating layer GI2, a second gate metal layer Gate2, an interlayer defining layer ILD, a first source-drain metal layer SD1, and a passivation layer PVX which are disposed between the substrate 01 and the planarization layer PLN1 and are sequentially laminated in the direction away from the substrate 01, and a second source-drain metal layer SD2 disposed between the planarization layer PLN1 and the planarization layer PLN2. The first source-drain metal layer SDI is coupled to the active layer ACT, and the second source-drain metal layer SD2 is coupled to the first source-drain metal layer SD1 and the anode Anode.

In some embodiments, the substrate 01 is made of a flexible material, for example, polyimide (P1). The active layer ACT is made of low temperature poly-silicon (P-Si). The first gate insulating layer GI1 and the second gate insulating layer GI2 are made of silicon oxide (SiOx). The first gate metal layer Gate1 and the second gate metal layer Gate2 are made of molybdenum (Mo). The above materials are illustrative only.

In some embodiments of the present disclosure, as can be further seen from FIG. 6, the anode Anode of the functional sub-pixel 022 has a first portion Anode1 close to the blue display sub-pixel 021-B in the display sub-pixel 021 and a second portion Anode2 away from the blue display sub-pixel 021-B in the display sub-pixel 021.

Moreover, the spacing d01 between the surface of the first portion Anode1 away from the substrate 01 and the substrate 01 is greater than the spacing d02 between the surface of the second portion Anode2 away from the substrate 01 and the substrate 01, that is, the portion of the anode Anode of the functional sub-pixel 022 close to the blue display sub-pixel 021-B is farther away from the substrate 01 than the portion of the anode Anode of the functional sub-pixel 022 away from the blue display sub-pixel 021-B is, 01. Therefore, the functional sub-pixel 022 emits the invisible light in the direction Z away from the blue display sub-pixel 021-B. thereby preventing the invisible light emitted from the functional sub-pixel 022 from radiating the blue display sub-pixel 021-B to damage the blue display sub-pixel 021-B. It is not limited to the blue display sub-pixel 021-B, that is, it may also be set that the portion of the anode Anode of the functional sub-pixel 022 close to the display sub-pixel of other color is farther away from the substrate 01 than the portion of the anode Anode of the functional sub-pixel 022 away from the display sub-pixel of the other color is.

It is to be noted that setting the spacing between the surface, away from the substrate 01, of the first portion Anode1 of the anode Anode of the functional sub-pixel 022 and the substrate 01 to be greater than the spacing between the surface of the second portion Anode2 away from the substrate 01 and the substrate 01 is that the planarization layer PLN2 is set to be inclined in the direction away from the blue display sub-pixel 021-B, as described in the above embodiments, such that the spacing between the surface of the first portion Anode1 away from the substrate 01 and the substrate 01 is greater than the spacing between the surface of the second portion Anode2 away from the substrate 01 and the substrate 01, which is the same as that the anode Anode of the functioning sub-pixel 022 is set to be inclined in the direction Z away from the anode Anode of the display sub-pixel 021, as described in the above embodiments. Alternatively, in some other embodiments, on the basis of the flatness of the planarization layer PLN2 shown in FIG. 7, the anode Anode is directly set to have the first portion Anode1 and the second portion Anode2 having different thicknesses, such that the spacing between the surface of the first portion Anode1 away from the substrate 01 and the substrate 01 is greater than the spacing between the surface of the second portion Anode2 away from the substrate 01 and the substrate 01. Alternatively, as described in the above embodiments, other film layers are additionally provided between the planarization layer PLN2 and the anode Anode, such that the spacing between the surface of the first portion Anode1 away from the substrate 01 and the substrate 01 is greater than the spacing between the surface of the second portion Anode2 away from the substrate 01 and the substrate 01. The implementations of making the spacing between the two portions of the anode Anode and the substrate 01 different are not limited in the embodiments of the present disclosure.

In some embodiments, FIG. 8 is a structural diagram of a circuit of a sub-pixel according to some embodiments of the present disclosure. As shown in FIG. 8, the display sub-pixel 021 and the functional sub-pixel 022 in the embodiments of the present disclosure both include a pixel circuit P1 and a light-emitting element L1. The light-emitting element L1 includes an anode Anode. a light-emitting layer EL, and a cathode layer Cathode that are sequentially laminated, and the pixel circuit P1 includes: a reset sub-circuit P11, a light emission control sub-circuit P12, a drive sub-circuit P13, and a potential adjustment sub-circuit P14.

The reset sub-circuit P11 is coupled to a reset terminal Reset, an initial power supply terminal Vinit, a first node N1, and the light-emitting element L1, and configured to control, based on a reset signal provided by the reset terminal Reset, the switching on and of the connection between the initial power supply terminal Vinit and the first node N1 and the switching on and of the connection between the initial power supply terminal Vinit and the light-emitting element L1.

For example, when the potential of the reset signal provided by the reset terminal Reset is a first potential, the reset sub-circuit P11 controls the connection between the initial power supply terminal Vinit and the first node N1 to be switched on, and controls the connection between the initial power supply terminal Vinit and the light-emitting element L1 to be switched on, such that the initial power supply terminal Vinit1 transmits an initial power supply signal to the first node N1 and the light-emitting element L1, thereby resetting the first node N1 and the light-emitting element L1. In addition, when the potential of the reset signal is a second potential, the reset sub-circuit P11 controls the connection between the initial power supply terminal Vinit and the first node N1 to be switched off, and controls the connection between the initial power supply terminal Vinit and the light-emitting element L1 to be switched off.

In some embodiments of the present disclosure, the first potential is an effective potential, the second potential is an ineffective potential, and the first potential is a low potential relative to the second potential. In some other embodiments, the first potential is a high potential relative to the second potential.

The light emission control sub-circuit P12 is coupled to a light emission control terminal EM, a driving power supply terminal VDD, a second node N2, a third node N3, and the light-emitting element L1, and configured to control, based on a light emission control signal provided by the light emission control terminal EM, the switching on and off of the connection between the driving power supply terminal VDD and the second node N2 and the switching on and off of the connection between the third node N3 and the light-emitting element L1.

For example, when the potential of the light emission control signal provided by the light emission control terminal EM is the first potential, the light emission control sub-circuit P12 controls the connection between the driving power supply terminal VDD and the second node N2 to be switched on, and controls the connection between the third node N3 and the light-emitting element L1 to be switched on, such that the driving power supply terminal VDD transmits a driving power supply signal to the second node N2 and the signal transmitted to the third node N3 is further transmitted to the light-emitting element L1. When the potential of the light emission control signal is the second potential, the light emission control sub-circuit P12 controls the connection between the driving power supply terminal VDD and the second node N2 to be switched off, and controls the connection between the third node N3 and the light-emitting element L1 to be switched off.

The drive sub-circuit P13 is coupled to the first node N1, the second node N2, and the third node N3, and configured to transmit a light emission driving signal to the third node N3 based on the potential of the first node N1 and the potential of the second node N2.

The potential adjustment sub-circuit P14 is coupled to the first node N1 and the driving power supply terminal VDD. and configured to adjust the potential of the first node N1 based on the driving power supply signal provided by the driving power supply terminal VDD.

In some embodiments, as can be seen from FIG. 8, the reset sub-circuit P11 and the light emission control sub-circuit P12 are both coupled to the first electrode of the light-emitting element L1, and the second electrode of the light-emitting element L1 is coupled to a pull-down power supply terminal VSS. The light-emitting element L1 emits light under the action of the voltage difference between the driving signal received at the first electrode thereof and a pull-down power supply signal provided by the pull-down power supply terminal VSS. In some embodiments, as described in the above embodiments, the first electrode of the light-emitting element L1 refers to the anode, and the second electrode refers to the cathode. In some other embodiments, the first electrode of the light-emitting element L1 refers to the cathode. and the second electrode refers to the anode.

At least one of the reset sub-circuit P11, the drive sub-circuit P13, and the potential adjustment sub-circuit P14 in the pixel circuit PI of the functional sub-pixel 022 and in the pixel circuit P1 of the display sub-pixel 021 is shared. For example, with reference to FIG. 8, all of the reset sub-circuit P11, the drive sub-circuit P13, and the potential adjustment sub-circuit P14 in the pixel circuits shown are shared, and only the light emission control sub-circuits P12 are independent of each other. For differentiation purposes, the light emission control sub-circuits P12 in the display sub-pixel 021 and the functional sub-pixel 022 are respectively marked as P12 and P12′ in the figure.

In some embodiments, as can be further seen from FIG. 8, the pixel circuit P, in the display sub-pixel 021 further includes: a data writing sub-circuit P15, coupled to a gate signal terminal Gate, a data signal terminal Data, the first node N1, the second node N2, and the third node N3, and configured to control, based on a gate driving signal provided by the gate signal terminal Gate, the switching on and off of the connection between the data signal terminal Data and the second node N2 and the switching on and off of the connection between the third node N3 with the first node N1.

For example, when the potential of the gate driving signal provided by the gate signal terminal Gate is the first potential, the data writing sub-circuit P15 controls the connection between the data signal terminal Data and the second node N2 to be switched on, and controls the connection between the third node N3 and the first node N1 to be switched on, such that the data signal terminal Data transmits a data signal to the second node N2 and the potential of the third node N3 is transmitted to the first node N1. When the potential of the gate driving signal is the second potential, the data writing sub-circuit P15 controls the connection between the data signal terminal Data and the second node N2 to be switched off, and controls the connection between the third node N3 and the first node N1 to be switched off.

In addition, the pixel circuit P1 in the functional sub-pixel 022 further includes a data writing sub-circuit shared with the data writing sub-circuit P15 included in the pixel circuit PI in the display sub-pixel 021. That is, the functional sub-pixel 022 further includes a data writing sub-circuit, and the data writing sub-circuit is shared with the data writing sub-circuit included in the display sub-pixel 021. Alternatively, only the display sub-pixel 021 includes the data writing sub-circuit described in the above embodiments, and the functional sub-pixel 022 does not include a data writing sub-circuit.

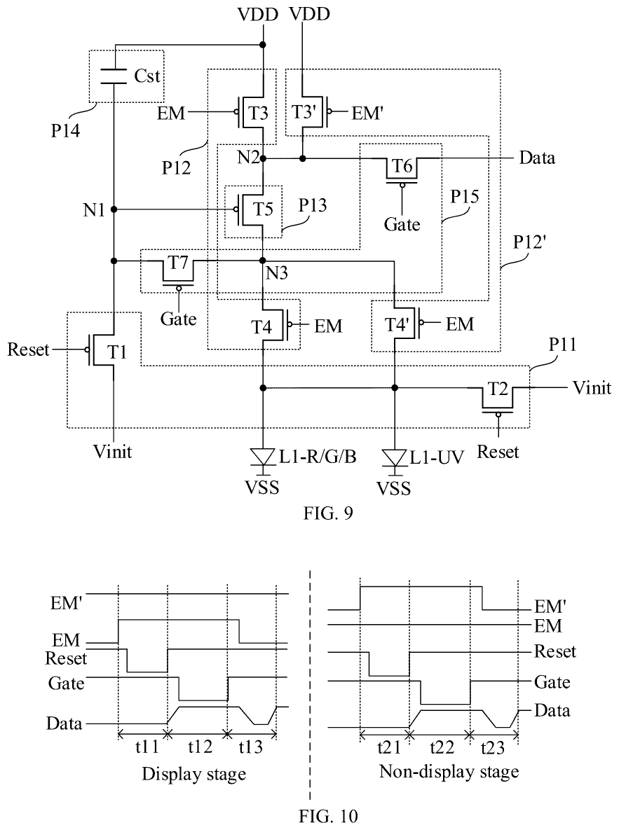

In some embodiments, based on FIG. 8, FIG. 9 shows a schematic structural diagram of a pixel circuit. As shown in FIG. 9, the reset sub-circuit P11 includes a first transistor T1 and a second transistor T2, the light emission control sub-circuit P12 includes a third transistor T3 and a fourth transistor T4, the drive sub-circuit P13 includes a fifth transistor T5, the potential adjustment sub-circuit P14 includes a storage capacitor Cst, and the data writing sub-circuit P15 includes a sixth transistor T6 and a seventh transistor T7.

The gate of the first transistor T1 and the gate of the second transistor T2 are both coupled to the reset terminal Reset, the first electrode of the first transistor T1 and the second electrode of the second transistor T2 are both coupled to the initial power supply terminal Vinit, the second electrode of the first transistor T1 is coupled to the first node N1, and the first electrode of the second transistor T2 is coupled to the light-emitting element L1.

The gate of the third transistor T3 and the gate of the fourth transistor T4 are both coupled to the light emission control terminal EM, the first electrode of the third transistor T3 is coupled to the driving power supply terminal VDD, the second electrode of the third transistor T3 is coupled to the second node N2, the first electrode of the fourth transistor T4 is coupled to the third node N3, and the second electrode of the fourth transistor T4 is coupled to the light-emitting element L1. It should be noted that in FIG. 9, for differentiation, the third transistors included in the display sub-pixel 021 and the functional sub-pixel 022 are respectively marked as T3 and T3′, and the fourth transistors are respectively marked as T4 and T4′, and the light emission control terminals are respectively marked as EM and EM′.

The gate of the fifth transistor T5 is coupled to the first node N1, the first electrode of the fifth transistor T5 is coupled to the second node N2, and the second electrode of the fifth transistor T5 is coupled to the third node N3.

The gate of the sixth transistor T6 and the gate of the seventh transistor T7 are both coupled to the gate signal terminal Gate, the first electrode of the sixth transistor T6 is coupled to the data signal terminal Data, the second electrode of the sixth transistor T6 is coupled to the second node N2, the first electrode of the seventh transistor T7 is coupled to the third node N3, and the second electrode of the seventh transistor T7 is coupled to the first node N1.

One terminal of the storage capacitor Cst is coupled to the driving power supply terminal VDD, and the other terminal of the storage capacitor Cst is coupled to the first node N1.

In some embodiments, in the case that the functional sub-pixel 022 includes the data writing sub-circuit P15, and the reset sub-circuit P11, the drive sub-circuit P13, the potential adjustment sub-circuit P14, and the data writing sub-circuit P15 are shared by the display sub-pixel 021 and the functional sub-pixel 022, as can be seen in conjunction with FIG. 9, the display sub-pixel 021 and the functional sub-pixel 022 share the following transistors: the first transistor T1, the second transistor T2, the fifth transistor T5, the sixth transistor T6, and the seventh transistor T7, and share the storage capacitor Cst. The third transistors T3 and the fourth transistors T4 are respectively independent of each other. In this way, not only the circuit structure can be simplified, but also the wiring can be simplified, thereby saving costs, simplifying the manufacturing process, and reducing the space occupied by each pixel, which lays the foundation for the design of the display panel with high resolution.

As described in the above embodiments, the functional sub-pixel 022 may not include the data writing sub-circuit P15, i.e., not include the sixth transistor T6 and the seventh transistor T7. because compared with the display sub-pixel 021 which emits visible light, there is no requirement for the difference of luminance intensity and luminance uniformity on the functional sub-pixel 022 which emits invisible light, and thus there is no need for compensation, for example, compensation for threshold voltage. It is only necessary to transmit an initial power supply signal to the first node N1 during the light-emitting process to ensure that the fifth transistor T5 can be reliably turned on, and the third transistor T3′ and the fourth transistor T4′ are controlled to be turned on to enable the light-emitting element L1 emit light. The luminance intensity is only related to the potential of the initial power supply signal. No writing data signal is required in the entire driving process, and there is no need to provide gate driving signals. Therefore, the power consumption of the drive circuit driving the pixels to emit light can be reduced.

In some embodiments, as can be further seen from FIG. 9, the transistors in the pixel circuit Pl are all P-type transistors. For the P-type transistor, the first potential is a low potential, and the second potential is a high potential, as described in the above embodiments. In some other embodiments, N-type transistors may also be used, and for the N-type transistor, the first potential is a high potential and the second potential is a low potential.

It should be noted that the pixel circuit P1 in the display sub-pixel 021 shown in FIG. 9 may be considered as a pixel circuit having a 7T1C structure (i.e., including 7 transistors and 1 capacitor). In some other embodiments, the pixel circuit P1 in the display sub-pixel 021 may also be of other structures, such as an 8T1C structure or a 9T2C structure. The pixel circuit P1 in the functional sub-pixel 022 is the same as the pixel circuit P1 in the display sub-pixel 021, which has the 7T1C structure shown in FIG. 9. Alternatively, since the requirement for luminance and intensity uniformity on the functional sub-pixel 022 is not high, a simpler pixel circuit than the pixel circuit P1 in the display sub-pixel 021 may be selected, as described in the above embodiments, for example, a pixel circuit having a 6T1C structure or a 2T1C structure. Alternatively, in some embodiments, a passive matrix (PM) is adopted to drive the functional sub-pixel 022 to emit light.

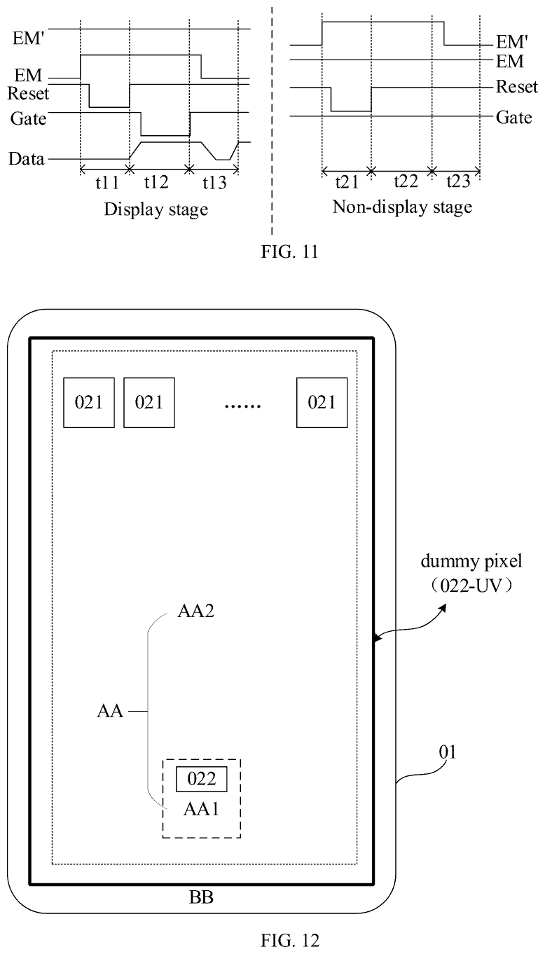

In some embodiments, FIG. 10 and FIG. 11 respectively show an operating timing diagram of a pixel circuit by taking an example where the pixel circuit PI in the display sub-pixel 021 includes the data writing sub-circuit P15 (i.e., the structure shown in FIG. 9), the pixel circuit Pl in the functional sub-pixel 022 does not include the data writing sub-circuit P15, and the transistors are P-type transistors, i.e., the first potential is a low potential (VGL) and the second potential is a high potential (VGH).

Referring to FIG. 10 and FIG. 11, the operation of the display panel includes a display stage and a non-display stage, and the display stage includes stages t11, t12, and t13 executed in sequence, and the non-display stage includes stages t21, t22, and t23 executed in sequence.

In stages t11, t12 and t13, the light emission control signal provided by the light emission control terminal EM′ coupled to the functional sub-pixel 022 remains at the high potential VGH, and accordingly, the third transistor T3′ and the fourth transistor T4′ remain in the off state. In stages t21, 122 and t23, the light emission control signal provided by the light emission control terminal EM coupled to the display sub-pixel 021 remains at the high potential VGH, and accordingly, the third transistor T3′ and the fourth transistor T4′ remain in the off state.

In stage t11, the potential of the light emission control signal provided by the light emission control terminal EM and the potential of the gate driving signal provided by the gate signal terminal Gate are both the high potential VGH, and the potential of the reset signal provided by the reset signal terminal Reset is the low potential VGL. Accordingly, the first transistor TI and the second transistor T2 are turned on, and the third transistor T3, the fourth transistor T4, the sixth transistor T6, and the seventh transistor T7 are turned off. Further, the initial power supply signal provided by the initial power supply terminal Vint is transmitted to the first node N1 through the turned-on first transistor T1 and is transmitted to the light-emitting element L1 through the turned-on second transistor T2, to reset the first node N1 and the light-emitting element L1. Accordingly, the fifth transistor T5 is turned on.

In stage t12, the potential of the light emission control signal provided by the light emission control terminal EM and the potential of the reset signal provided by the reset signal terminal Reset are both the high potential VGH, and the potential of the gate driving signal provided by the gate signal terminal Gate is the low potential VGL. Accordingly, the sixth transistor T6 and the seventh transistor T7 are turned on, and the first transistor Tl. the second transistor T2, the third transistor T3, and the fourth transistor T4 are turned off. Furthermore, under the coupling effect of the storage capacitor Cst, the potential of the first node N, remains as the low potential VGL of the previous stage, and the fifth transistor T5 remains turned-on. Further, the data signal provided by the data signal terminal Data is transmitted to the second node N2 through the turned-on sixth transistor T6, and the connection between the third node N3 and the first node N1 is switched on. Accordingly, the data signal written into the second node N2 and the threshold voltage of the fifth transistor T5 are written into the first node N1, so as to compensate for the threshold voltage of the fifth transistor T5 during subsequent light emission.

In stage t13, the potential of the reset signal provided by the reset signal terminal Reset and the potential of the gate driving signal provided by the gate signal terminal Gate are both the high potential VGH, and the potential of the light emission control signal provided by the light emission control terminal EM is the low potential VGL. Accordingly, the third transistor T3 and the fourth transistor T4 are turned on, and the first transistor T1, the second transistor T2, the sixth transistor T6, and the seventh transistor T7 are turned off. Furthermore, under the coupling effect of the storage capacitor Cst, the potential of the first node N1 remains at the low potential VGL of the previous stage, and the fifth transistor T5 remains turned-on. Further, a path is formed between the driving power supply terminal VDD and the pull-down power supply terminal VSS through the third transistor T3, the fifth transistor T5. and the fourth transistor T4 which are turned-on, and the fifth transistor T5 generates a light emission driving signal (e.g., a drive current) based on the potential of the first node N1 and the potential of the second node N2 and transmits the light emission driving signal to the light-emitting element L1 through the fourth transistor T4. thereby driving the light-emitting element L1 to emit light. Since the third transistor T3′ and the fourth transistor T4′ remains turned-off during the display stage, only the light-emitting element L1-R/G/B in the display sub-pixel 021 is driven to emit light, and the light-emitting element L1-UV in the functional sub-pixel 022 is not driven to emit light.

For the functional sub-pixel 022 that includes the data writing sub-circuit P15, reference is made to FIG. 10.

In stage 121, the potential of the light emission control signal provided by the light emission control terminal EM′ and the potential of the gate driving signal provided by the gate signal terminal Gate are both the high potential VGH, and the potential of the reset signal provided by the reset signal terminal Reset is the low potential VGL. Accordingly, the first transistor T1 and the second transistor T2 are turned on, and the third transistor T3′. the fourth transistor T4′, the sixth transistor T6, and the seventh transistor T7 are turned off. Further, the initial power supply signal provided by the initial power supply terminal Vint is transmitted to the first node N1 through the turned-on first transistor T1 and is transmitted to the light-emitting element L1 through the turned-on second transistor T2, to reset the first node N1 and the light-emitting element L1. Accordingly, the fifth transistor T5 is turned on.

In stage t22, the potential of the light emission control signal provided by the light emission control terminal EM′ and the potential of the reset signal provided by the reset signal terminal Reset are both the high potential VGH, and the potential of the gate driving signal provided by the gate signal terminal Gate is the low potential VGL. Accordingly, the sixth transistor T6 and the seventh transistor T7 are turned on, and the first transistor T1, the second transistor T2, the third transistor T3′, and the fourth transistor T4′ are turned off. Furthermore, under the coupling effect of the storage capacitor Cst, the potential of the first node N1 remains as the low potential VGL of the previous stage, and the fifth transistor T5 remains turned-on. Further, the data signal provided by the data signal terminal Data is transmitted to the second node N2 through the turned-on sixth transistor T6, and the connection between the third node N3 and the first node N1 is switched on. Accordingly, the data signal written into the second node N2 and the threshold voltage of the fifth transistor T5 are written into the first node N1, so as to compensate for the threshold voltage of the fifth transistor T5 during subsequent light emission.

In stage 123, the potential of the reset signal provided by the reset signal terminal Reset and the potential of the gate driving signal provided by the gate signal terminal Gate are both the high potential VGH, and the potential of the light emission control signal provided by the light emission control terminal EM′ is the low potential VGL. Accordingly, the third transistor T3′ and the fourth transistor T4′ are turned on, and the first transistor T1, second transistor T2, the sixth transistor T6, and the seventh transistor T7 are turned off. Furthermore, under the coupling effect of the storage capacitor Cst, the potential of the first node N1 remains as the low potential VGL of the previous stage, and the fifth transistor T5 remains turned-on. Further, a path is formed between the driving power supply terminal VDD and the pull-down power supply terminal VSS through the third transistor T3′, the fifth transistor T5, and the fourth transistor T4′ which are turned-on, and the fifth transistor T5 generates a light emission driving signal (e.g., a drive current) based on the potential of the first node N1 and the potential of the second node N2 and transmits the light emission driving signal to the light-emitting element L1 through the fourth transistor T4′, thereby driving the light-emitting element L1 to emit light. Since the third transistor T3 and the fourth transistor T4 remain tuned-off in the non-display stage, only the light-emitting element L1-UV in the functional sub-pixel 022 is driven to emit light, and the light-emitting element L1-R/G/B in the display sub-pixel 021 is not driven to emit light.

For the functional sub-pixel 022 that does not include the data writing sub-circuit P15. reference is made to FIG. 11.

In stages t21 to t23. the potential of the gate driving signal provided by the gate signal terminal Gate coupled to the display sub-pixel 021 remains as the high potential VGH, and the sixth transistor T6 and the seventh transistor T7 are turned off. The remaining signal terminals (light emission control terminal EM′ and reset signal terminal Reset) provide the same signals as in FIG. 10, and the pixel circuits perform the same functions, which are not repeated herein.

In some embodiments. FIG. 12 is a schematic structural diagram of another display panel according to some embodiments of the present disclosure. As shown in FIG. 12, the substrate 01 has a display region AA and a peripheral region BB that at least partially surrounds the display region AA. For example, in the display panel shown in FIG. 12, the peripheral region BB of the substrate 01 surrounds the display region AA.

The display sub-pixels 021 are disposed in the display region AA, and the functional sub-pixels 022 are disposed in at least one of the display region AA and the peripheral region BB. For example, in the display panel shown in FIG. 12, the functional sub-pixels 022 (e.g., UV) are disposed in the display region AA and the peripheral region BB.

Furthermore, with continued reference to FIG. 12, the display region AA includes a fingerprint region AA1 provided with a fingerprint sensor and a main display region AA2 that at least partially surrounds the fingerprint region. The display sub-pixels are disposed in the fingerprint region AA1 and the main display region AA2, and the functional sub-pixels 022 are disposed in the fingerprint region AA1.

It should be noted that the functional sub-pixels 022 for emitting ultraviolet light are provided in the fingerprint region AA2. Since the fingerprint region AA1 is generally configured to identify fingerprints and has the highest touch frequency, the fingerprint region AA1 can be disinfected periodically by providing the functional sub-pixels 022 for emitting ultraviolet light in the fingerprint region AA1.

In some embodiments, the display panel in the embodiments of the present disclosure further includes a dummy pixel circuit disposed in the peripheral region BB. That is, in the display panel having the structure shown in FIG. 12, a circle of dummy pixel circuits is usually added to the periphery of the display region AA.

The dummy pixel circuit refers to a pixel circuit that is provided in the peripheral region BB and has the same structure as the pixel circuit in the display region AA, but is not coupled to the light-emitting element included in any one of the display sub-pixels 021. The dummy pixel circuit is provided mainly to ensure a better working performance of the pixel circuit.

In the embodiments of the present disclosure, the pixel circuit PI included in the functional sub-pixel 022 is shared with the dummy pixel circuit. That is, the dummy pixel circuits that are provided in the peripheral region BB and not coupled to the light-emitting elements L1 emitting the visible light are reused as the pixel circuits of the functional sub-pixels 022 and are coupled to the light-emitting elements L1 included in the functional sub-pixels 022 to drive the light-emitting elements L1 to emit invisible light similar to the ultraviolet light. In this way, not only the invisible light can be emitted from the periphery of the display region AA. but also the normal light emission of the display sub-pixels 021 in the display region AA is not affected. i.e., the normal display of the display region AA is not affected.

It is to be noted that in the scenario where the functional sub-pixels 022 are provided in the fingerprint region AA1, the dummy pixel circuits in the peripheral region BB can still be used to couple the light-emitting elements L1 of the functional sub-pixels 022, that is, the light-emitting elements L1 included in the functional sub-pixels 022 are provided in the fingerprint region AA1, and the pixel circuits P1 included in the functional sub-pixels 022 are provided in the peripheral region BB. In this way, a better transmittance rate of the fingerprint region AA1 can be ensured. On the basis of this embodiment, the pixel circuits P1 disposed in the peripheral region BB and the light-emitting elements L1 disposed in the fingerprint region AA1 are coupled by transparent conductive wires, thereby further ensuring a better transmittance rate of the fingerprint region AA1. In some embodiments, the material of the transparent conductive wires includes indium tin oxide (ITO).

It can be known in combination with the above embodiments that, in one aspect, the display panel provided in the embodiments of the present disclosure can achieve self-cleaning of the surface of the display panel and reduce the probability of disease transmission while achieving the display function, and the display panel has richer functions. In another aspect, in the display panel provided in the embodiments of the present disclosure, the design of the functional sub-pixels (e.g., UV) that emit invisible light is optimized, and the light-absorbing layer 03 is also provided to absorb the invisible light, which can reduce the damage to the display sub-pixels 021 emitting the visible light and prolong the service life. In still another aspect, in the embodiments of the present disclosure, the functional sub-pixel 022 and the display sub-pixel 021 share some devices of the pixel circuits, which can achieve a high PPI design. In still another aspect, in the embodiments of the present disclosure, the dummy pixel circuit in the peripheral region BB is reused as the pixel circuit of the functional sub-pixel 022, without affecting the normal display of the display region AA. The display panel provided in the embodiments of the present disclosure is applicable to a wider range of scenarios.

In summary: the embodiments of the present disclosure provide a display panel. The display panel includes a substrate and a plurality of pixels disposed on a side of the substrate. Each pixel includes a plurality of display sub-pixels for emitting different colors of visible light and at least one functional sub-pixel for emitting invisible light. On the basis that the plurality of display sub-pixels are lit to emit different colors of visible light, the display panel displays an image. On the basis that the functional sub-pixels emit invisible light (e.g., ultraviolet light), the display panel performs a function (e.g., sterilizing function) that matches the invisible light. Thus, the display panel provided in the embodiments of the present disclosure has richer functions.

In addition. in the embodiments of the present disclosure, the functional sub-pixels are spaced apart from the display sub-pixels in any direction, and a light-absorbing layer configured to absorb the invisible light is further provided between the functional sub-pixel and the display sub-pixel that are adjacent to each other. Therefore, on the premise that the functions are enriched, the display sub-pixels can be prevented from being damaged due to the radiation of the invisible light emitted from the functional sub-pixels, and the display sub-pixels are be protected.

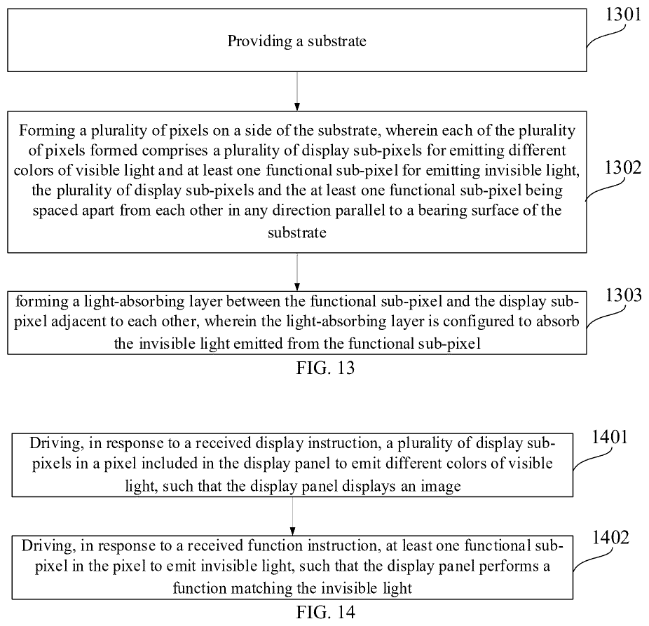

FIG. 13 is a flowchart of a method for manufacturing a display panel according to some embodiments of the present disclosure. The method is applicable for manufacturing the display panel as provided in the above embodiments. As shown in FIG. 13, the method includes the following steps.

In step 1301, a substrate is provided.

In step 1302, a plurality of pixels are formed on a side of the substrate, the formed pixel includes a plurality of display sub-pixels for emitting different colors of visible light and at least one functional sub-pixel for emitting invisible light, and the plurality of display sub-pixels are spaced apart from the at least one functional sub-pixel in any direction parallel to the bearing surface of the substrate.

In step 1303, a light-absorbing layer is formed between the functional sub-pixel and the display sub-pixel that are adjacent to each other, and the light-absorbing layer is configured to absorb the invisible light emitted from the functional sub-pixel.

In some embodiments, as described in the above embodiments, the formed display sub-pixel and functional sub-pixel both include an anode, a light-emitting layer, and a cathode layer which are laminated in a direction away from the substrate, and at least the anodes and the light-emitting layers of the display sub-pixel and the functional sub-pixel are respectively spaced apart from each other. On this basis, the manufacturing method further includes forming a planarization layer between the substrate and the anode using a halftone mask.

The thickness of the portion of the planarization layer that overlaps the anode of the functional sub-pixel is greater than or equal to the thickness of the portion of the planarization layer that overlaps the anode of the display sub-pixel, such that in the functional sub-pixel and the display sub-pixel adjacent to each other, the spacing between the anode of the functional sub-pixel and the substrate is greater than or equal to the spacing between the anode of the display sub-pixel and the substrate; and/or the portion of the planarization layer that overlaps the anode of the functional sub-pixel is inclined away from the portion of the planarization layer that overlaps the anode of the display sub-pixel, such that in the functional sub-pixel and the display sub-pixel adjacent to each other, the side of the anode of the functional sub-pixel away from the substate is inclined in the direction away from the anode of the display sub-pixel.

In summary, the embodiments of the present disclosure provide a method for manufacturing a display panel. The display panel manufactured by the method includes a substrate and a plurality of pixels disposed on a side of the substrate. Each of the pixels includes a plurality of display sub-pixels for emitting different colors of visible light, and further includes at least one functional sub-pixel for emitting invisible light. On the basis that the plurality of display sub-pixels are lit to emit different colors of visible light, the display panel can display images. On the basis that the functional sub-pixel emits invisible light (e.g., ultraviolet light), the display panel can implement functions matching the type of the invisible light (e.g., sterilization). Thus, the display panel provided the embodiments of the present disclosure has richer functions. In addition, the functional sub-pixels formed by this method are spaced apart from the display sub-pixels formed by this method in any direction, and a light-absorbing layer for absorbing the invisible light is provided between the functional sub-pixel and the display sub-pixel adjacent to each other. Thus, on the basis that the functions are enriched, the display sub-pixels are prevented from being damaged due to the radiation of the invisible light emitted from the functional sub-pixels, thereby protecting the display sub-pixels.

FIG. 14 is a flowchart of a method for driving a display panel according to some embodiments of the present disclosure. This method is applicable for driving the display panel as described in the above embodiments. As shown in FIG. 14, the driving method includes the following steps.

In step 1401, a plurality of display sub-pixels in a pixel included in the display panel are driven to emit different colors of visible light in response to a received display instruction, such that the display panel display an image.

In step 1402, at least one functional sub-pixel in the pixel is driven to emit invisible light in response to a received function instruction, such that the display panel performs a function matching the invisible light.

It should be noted that the function matching the invisible light refer to a function that can be achieved by the invisible light. For example, according to the above embodiments, if the invisible light is ultraviolet light, the function matching the invisible light includes some cleaning and sterilization and disinfection functions; and if the invisible light is infrared light, the function matching the invisible light includes therapy functions and imaging functions.

In summary, the embodiments of the present disclosure provide a method for driving a display panel. The method can drive the display panel to display images and can also drive the display panel to perform a non-display function matching the invisible light. Thus, the display panel in the embodiments of the present disclosure has richer functions.

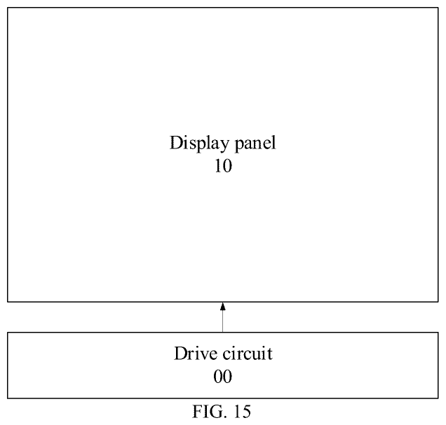

FIG. 15 is a schematic structural diagram of a display device according to some embodiments of the present disclosure. As shown in FIG. 15, the display device includes a drive circuit 10 and the display panel 00 as described in the above embodiments.

The drive circuit 10 is coupled to the display panel 00, and the drive circuit 10 is configured to drive a plurality of display sub-pixels 021 in a pixel 02 included in the display panel 00 to emit different colors of visible light, and is configured to drive at least one functional sub-pixel 022 in the pixel 02 to emit invisible light. That is, the drive circuit 10 receives a display instruction and a function instruction and performs the method for driving the display panel as provided in the above embodiments.

In some embodiments, the display device may be any product or component having a display function, such as an OLED display device and an active-matrix OLED (AMOLED) display device.

The terms used in the embodiments of the present disclosure are merely used for explaining the embodiments of the present disclosure, but not limit the present disclosure. Unless otherwise defined, the technical terms or scientific terms used in the embodiments of the present disclosure shall have the general meanings understood by those of ordinary skill in the art to which the present disclosure belongs.

For example, the terms “first”, “second”, “third” and the like used the descriptions and claims of the present disclosure do not indicate any order, quantity; or importance, but rather are used to distinguish between different components.

Similarly, the terms “a/an”, “one” and the like do not indicate a limitation in quantity, but rather indicate the existence of at least one.

The terms “include”, “comprise” and the like mean that the element or object preceding “include” or “comprise” encompasses the elements, objects, or equivalents thereof listed after “include” or “comprise”, without excluding other elements or objects.

The terms “on”, “under”, “left”, “right” and the like are used indicate the relative positional relationship only. When the absolute position of the described object is changed, the relative positional relationship may be changed accordingly. “Connecting” or “coupling” refers to an electrical connection.

The expression “and/or” indicates three kinds of relationships. For example, A and/or B means three circumstances, i.e., A exits alone, A and B exit concurrently, and B exits alone. The character “/” generally indicates an “or” relationship between the objects associated before and after.

Those skilled in the art can clearly understand that, for the convenience and brevity of descriptions, for the specific operating processes of the gate driving circuit, the shift register unit, various circuits and sub-circuits described above, reference can be made to the corresponding processes in the method embodiments, and details are not repeated herein.

Described above are optional embodiments of the present disclosure and are not intended to limit the present disclosure. Within the spirit and principles of the present disclosure, any variations, equivalent substitutions, improvements and the like shall be included in the protection scope of the present disclosure.

1. A display panel, comprising:
a substrate;
a plurality of pixels disposed on a side of the substrate, wherein each of the plurality of pixels comprises a plurality of display sub-pixels for emitting different colors of visible light and at least one functional sub-pixel for emitting invisible light, the plurality of display sub-pixels being spaced apart from the at least one functional sub-pixel in any direction parallel to a bearing surface of the substrate; and
a light-absorbing layer disposed between a functional sub-pixel and a display sub-pixel adjacent to each other, wherein the light-absorbing layer is configured to absorb invisible light emitted from the functional sub-pixel.

2. The display panel according to claim 1, wherein
a size of each of the at least one functional sub-pixel is smaller than a size of any one of the plurality of display sub-pixels; and/or
the invisible light comprises ultraviolet light or infrared light.

3. The display panel according to claim 2, wherein each of the plurality of pixels comprises a red display sub-pixel for emitting red visible light, a green display sub-pixel for emitting green visible light, a blue display sub-pixel for emitting blue visible light, and a functional sub-pixel; wherein
the red display sub-pixel, the functional sub-pixel, and the green display sub-pixel are disposed in sequence in a first direction parallel to the bearing surface of the substrate, and each of the red display sub-pixel, the functional sub-pixel, and the green display sub-pixel is disposed in sequence with the blue display sub-pixel in a second direction parallel to the bearing surface of the substrate, the first direction intersecting the second direction; and
an opening width of the functional sub-pixel, an opening width of the green display sub-pixel, an opening width of the red display sub-pixel, and an opening width of the blue display sub-pixel increase in sequence in the first direction; and an opening width of the functional sub-pixel, an opening width of the green display sub-pixel, an opening width of the red display sub-pixel, and an opening width of the blue display sub-pixel are all equal in the second direction.

4. The display panel according to claim 3, wherein a spacing between the functional sub-pixel and the blue display sub-pixel is greater than a spacing between the functional sub-pixel and the red display sub-pixel, and is greater than a spacing between the functional sub-pixel and the green display sub-pixel.

5. The display panel according to claim 3, wherein the opening width of the functional sub-pixel in the first direction is less than the opening width of the functional sub-pixel in the second direction.

6. (canceled)

7. The display panel according to claim 1, wherein each of the plurality of display sub-pixels and each of the at least one functional sub-pixel comprise an anode, a light-emitting layer, and a cathode layer that are laminated in a direction away from the substrate; at least the anodes and the light-emitting layers in the plurality of display sub-pixels and the at least one functional sub-pixel being respectively spaced apart from each other;
wherein the light-absorbing layer is disposed between the anode of the at least one functional sub-pixel and the anodes of the plurality of display sub-pixels.

8. The display panel according to claim 7, further comprising: a pixel defining layer disposed between an anode of a functional sub-pixel and an anode of a display sub-pixel that are adjacent to each other; wherein
the pixel-defining layer is added with a light-absorbing material for absorbing invisible light emitted from the functional sub-pixel, the light-absorbing layer being the same as the pixel-defining layer; or
the light-absorbing layer is disposed between the anodes and the pixel defining layer, and the light-absorbing layer is added with a light-absorbing material for absorbing invisible light emitted from the functional sub-pixel.

9. The display panel according to claim 8, wherein the light-absorbing material comprises at least one of a compound based on benzotriazoles or a compound based on o-hydroxyphenyltriazines.

10. The display panel according to claim 7, wherein there is one of:
in the functional sub-pixel and the display sub-pixel adjacent to each other, a spacing between a side of the anode of the functional sub-pixel away from the substrate and the substrate is greater than or equal to a spacing between a side of the anode of the display sub-pixel away from the substrate and the substrate;
in the functional sub-pixel and the display sub-pixel adjacent to each other, the anode of the functional sub-pixel is inclined in a direction away from the anode of the display sub-pixel; or
the anode of the functional sub-pixel comprises a first portion close to a blue display sub-pixel in the plurality of display sub-pixels and a second portion away from the blue display sub-pixel in the plurality of display sub-pixels, wherein a spacing between a surface of the first portion away from the substrate and the substrate is greater than a spacing between a surface of the second portion away from the substrate and the substrate.

11. (canceled)

12. The display panel according to claim 10, further comprising: a planarization layer disposed between the substrate and the anodes; wherein
a thickness of a portion of the planarization layer that overlaps the anode of the functional sub-pixel is greater than or equal to a thickness of a portion of the planarization layer that overlaps the anode of the display sub-pixel, such that in the functional sub-pixel and the display sub-pixel adjacent to each other, the spacing between the side of the anode of the functional sub-pixel away from the substrate and the substrate is greater than or equal to the spacing between the side of the anode of the display sub-pixel away from the substrate and the substrate; and/or
the portion of the planarization layer that overlaps the anode of the functional sub-pixel is inclined away from the portion of the planarization layer that overlaps the anode of the display sub-pixel, such that in the functional sub-pixel and the display sub-pixel adjacent to each other, the anode of the functional sub-pixel is inclined in a direction away from the anode of the display sub-pixel.

13. (canceled)

14. The display panel according to claim 1, wherein each of the plurality of display sub-pixels and each of the at least one functional sub-pixel comprise a pixel circuit and a light-emitting element; the pixel circuit in each of the plurality of display sub-pixels and the pixel circuit in each of the at least one functional sub-pixel both comprising:
a reset sub-circuit, coupled to a reset terminal, an initial power supply terminal, a first node, and the light-emitting element, and configured to control, based on a reset signal provided by the reset terminal, switching on and off of a connection between the initial power supply terminal and the first node and switching on and off of a connection between the initial power supply terminal and the light-emitting element;
a light emission control sub-circuit, coupled to a light emission control terminal, a driving power supply terminal, a second node, a third node, and the light-emitting element, and configured to control, based on a light emission control signal provided by the light emission control terminal, switching on and off of a connection between the driving power supply terminal and the second node and switching on and off of a connection between the third node and the light-emitting element;
a drive sub-circuit, coupled to the first node, the second node, and the third node, and configured to transmit a light emission driving signal to the third node based on a potential of the first node and a potential of the second node; and
a potential adjustment sub-circuit, coupled to the first node and the driving power supply terminal, and configured to adjust the potential of the first node based on a driving power supply signal provided by the driving power supply terminal;
the pixel circuit in each of the plurality of display sub-pixels further comprising: a data writing sub-circuit, coupled to a gate signal terminal, a data signal terminal, the first node, the second node, and the third node, and configured to control, based on a gate driving signal provided by the gate signal terminal, switching on and off of a connection between the data signal terminal and the second node and switching on and off of a connection between the third node and the first node;
wherein in the pixel circuit of each of the plurality of display sub-pixels and the pixel circuit of each of the at least one functional sub-pixel, at least one of the reset sub-circuit, the drive sub-circuit, and the potential adjustment sub-circuit is shared.

15. The display panel according to claim 14, wherein the pixel circuit of each of the at least one functional sub-pixel further comprises a data writing sub-circuit shared with the data writing sub-circuit included in the pixel circuit in each of the plurality of display sub-pixels.

16. The display panel according to claim 14, wherein the reset sub-circuit comprises a first transistor and a second transistor; the light emission control sub-circuit comprises a third transistor and a fourth transistor; the drive sub-circuit comprises a fifth transistor; the data writing sub-circuit comprises a sixth transistor and a seventh transistor; and the potential adjustment sub-circuit comprises a storage capacitor; wherein
a gate of the first transistor and a gate of the second transistor are coupled to the reset terminal, a first electrode of the first transistor and a second electrode of the second transistor are coupled to the initial power supply terminal, a second electrode of the first transistor is coupled to the first node, and a first electrode of the second transistor is coupled to the light-emitting element;
a gate of the third transistor and a gate of the fourth transistor are coupled to the light emission control terminal, a first electrode of the third transistor is coupled to the driving power supply terminal, a second electrode of the third transistor is coupled to the second node, a first electrode of the fourth transistor is coupled to the third node, and a second electrode of the fourth transistor is coupled to the light-emitting element;
a gate of the fifth transistor is coupled to the first node, a first electrode of the fifth transistor is coupled to the second node, and a second electrode of the fifth transistor is coupled to the third node;
a gate of the sixth transistor and a gate of the seventh transistor are coupled to the gate signal terminal, a first electrode of the sixth transistor is coupled to the data signal terminal, a second electrode of the sixth transistor is coupled to the second node, a first electrode of the seventh transistor is coupled to the third node, and a second electrode of the seventh transistor is coupled to the first node; and
one terminal of the storage capacitor is coupled to the driving power supply terminal, and another terminal of the storage capacitor is coupled to the first node.

17. The display panel according to claim 1, wherein the substrate has a display region and a peripheral region at least partially surrounding the display region;
wherein the plurality of display sub-pixels are disposed in the display region, and the at least one functional sub-pixel is disposed in at least one of the display region or the peripheral region.

18. The display panel according to claim 17, further comprising: a dummy pixel circuit disposed in the peripheral region;
wherein a pixel circuit included in each of the at least one functional sub-pixel is shared with the dummy pixel circuit.

19. The display panel according to claim 17, wherein the at least one functional sub-pixel is disposed in the display region; and the display region comprises a fingerprint region provided with a fingerprint sensor and a main display region at least partially surrounding the fingerprint region;
wherein the plurality of display sub-pixels are disposed in the fingerprint region and the main display region, and the at least one functional sub-pixel is disposed in the fingerprint region.

20. A method for manufacturing a display panel, applicable for manufacturing the display panel according to claim 1; the method comprising:
providing a substrate;
forming a plurality of pixels on a side of the substrate, wherein each of the plurality of pixels formed comprises a plurality of display sub-pixels for emitting different colors of visible light and at least one functional sub-pixel for emitting invisible light, the plurality of display sub-pixels being spaced apart from the at least one functional sub-pixel in any direction parallel to a bearing surface of the substrate; and
forming a light-absorbing layer between a functional sub-pixel and a display sub-pixel adjacent to each other, wherein the light-absorbing layer is configured to absorb invisible light emitted from the functional sub-pixel.

21. The method according to claim 20, wherein each of the plurality of display sub-pixels and each of the at least one functional sub-pixel comprise an anode, a light-emitting layer, and a cathode layer that are laminated in a direction away from the substrate; at least the anodes and the light-emitting layers in the plurality of display sub-pixels and the at least one functional sub-pixel being respectively spaced apart from each other; the method further comprising:
forming a planarization layer between the substrate and the anodes using a halftone mask; wherein
a thickness of a portion of the formed planarization layer that overlaps the anode of the functional sub-pixel is greater than or equal to a thickness of a portion of the planarization layer that overlaps the anode of the display sub-pixel, such that in the functional sub-pixel and the display sub-pixel adjacent to each other, a spacing between a side of the anode of the functional sub-pixel away from the substrate and the substrate is greater than or equal to a spacing between a side of the anode of the display sub-pixel away from the substrate and the substrate; and/or
the portion of the formed planarization layer that overlaps the anode of the functional sub-pixel is inclined away from the portion of the planarization layer that overlaps the anode of the display sub-pixel, such that in the functional sub-pixel and the display sub-pixel adjacent to each other, the anode of the functional sub-pixel is inclined in a direction away from the anode of the display sub-pixel.

22. A method for driving a display panel, applicable for driving the display panel according to claim 1; the method comprising:
driving, in response to a received display instruction, a plurality of display sub-pixels in a pixel included in the display panel to emit different colors of visible light, such that the display panel displays an image; and
driving, in response to a received function instruction, at least one functional sub-pixel in the pixel to emit invisible light, such that the display panel performs a function matching the invisible light.

23. A display device, comprising: a drive circuit, and a display panel;
wherein the display panel comprises:
a substrate;
a plurality of pixels disposed on a side of the substrate, wherein each of the plurality of pixels comprises a plurality of display sub-pixels for emitting different colors of visible light and at least one functional sub-pixel for emitting invisible light, the plurality of display sub-pixels being spaced apart from the at least one functional sub-pixel in any direction parallel to a bearing surface of the substrate; and
a light-absorbing layer disposed between a functional sub-pixel and a display sub-pixel adjacent to each other, wherein the light-absorbing layer is configured to absorb invisible light emitted from the functional sub-pixel;
wherein the drive circuit is coupled to the display panel, and the drive circuit is configured to drive a plurality of display sub-pixels in a pixel included in the display panel to emit different colors of visible light and configured to drive at least one functional sub-pixel in the pixel to emit invisible light.
